(19) United States
(12) Patent Application Publication
(10) Pub. No.: US 2011/0024873 A1
(43) Pub. Date: Feb. 3, 2011

(54) SEMICONDUCTOR DEVICE HAVING A FUSE REGION AND METHOD FOR FORMING THE SAME

(76) Inventor: Kyung-Jin LEE, Gyeonggi-do (KR)

Correspondence Address: IP & T GROUP LLP, 7700 Little River Turnpike, Suite 207, Annandale, VA, 22003, US

(21) Appl. No.: 12/830,712

(22) Filed: Jul. 6, 2010

(30) Foreign Application Priority Data
Jul. 31, 2009 (KR) 10-2009-0070658

(51) Int. Cl. H01L 23/525; H01L 21/768

(52) U.S. Cl. 257/529; 438/601; 257/E23.149; 257/E21.592

(57) ABSTRACT

A semiconductor device having a fuse region, the fuse region includes a conductive pattern and a fuse box formed to partially expose the conductive pattern which have an inclined edge on a bottom surface.

### CROSS-REFERENCE TO RELATED APPLICATIONS

The present application claims priority of Korean Patent Application No. 10-2009-0070658, filed on Jul. 31, 2009, which is incorporated herein by reference in its entirety.

### BACKGROUND OF THE INVENTION

Exemplary embodiments of the present invention relate to a technology for fabricating a semiconductor device, and more particularly, to a fuse region and technology for fabricating the fuse region, for example, to a fuse region including a dual fuse of a semiconductor device.

In general, redundancy cells for replacing defective cells are formed in the semiconductor memory device for improving the production yield, and the replacement process is referred to as a repair process.

A semiconductor device includes a fuse region for the above-described repair process. Typically, a fuse region includes a fuse and a fuse box which is formed in a protective layer covering the fuse and exposes a portion of the fuse. The fuse may be formed as a single fuse, which is formed of a single pattern according to the characteristics of the semiconductor device, or the fuse may be formed as a dual fuse, which may be formed of a plurality of patterns spaced apart from each other on the same line by a predetermined distance between the patterns.

FIGS. 1A and 1B illustrate a fuse region of a conventional semiconductor device including a dual fuse. FIG. 1A is a plane figure illustrating the fuse region of the semiconductor device, and FIG. 1B is a cross-sectional view obtained by cutting the fuse region shown in FIG. 1A along a line X-X′. FIG. 2 is a photograph showing a problem of the conventional technology.

Referring to FIGS. 1A and 1B, the fuse region of the conventional semiconductor device includes a dual fuse 14, a wiring layer 12, a plurality of plugs 13, an insulation layer 15, a protective layer 16, a first fuse box 17A, and a second fuse box 17B. The dual fuse 14 includes a first pattern 14A and a second pattern 14B positioned to be spaced apart on the same line by a predetermined distance. The wiring layer 12 is formed under the dual fuse 14. The insulation layer 15 fills a space between the wiring layer 12 and the dual fuse 14. The plurality of the plugs 13 electrically connect the dual fuse 14 with the wiring layer 12. The protective layer 16 covers the dual fuse 14. The first and second fuse boxes 17A and 17B are formed in the protective layer 16 to partially expose the first and second patterns 14A and 14B, respectively.

According to the above-described conventional technology, however, stress 100 may be concentrated to the edges of the bottom surfaces of the fuse boxes 17, for example, due to the sharp edges of the bottom surfaces of the fuse boxes 17, and as a result, the bottom surfaces of the fuse boxes 17 may crack. In particular, the crack may occur in the edges of the bottom surface where the first fuse box 17A and the second fuse box 17B face each other (see reference symbol ‘A’ of FIG. 1B and FIG. 2), because the edges of the bottom surfaces of the fuse boxes 17 have sharp shapes, and also because the protective layer 16 between the first fuse box 17A and the second fuse box 17B, and over the wiring layer 12 is isolated by the first fuse box 17A and the second fuse box 17B and a volume of the protective layer 16 may be too small to withstand the stress 100.

Here, since the plugs 13 are positioned under the protective layer 16 between the first and second fuse boxes 17A and 17B, the crack occurring on the edges of the bottom surfaces of the fuse boxes 17 may grow to a lower structure to electrically disconnect, for example, the plugs 13, which electrically connect the first and second patterns 14A and 14B (see reference symbol ‘A’ of FIG. 1B and FIG. 2). This may cause a defect of a repair fuse because the dual fuse 14 which is not electrically disconnected, i.e. a non-repaired fuse, may be recognized as a disconnected dual fuse 14, i.e. a repaired fuse. As a result, the repair yield and the reliability of a semiconductor device may be deteriorated.

A probability of occurrence of the crack may increase as the integration degree of a semiconductor device increases and the size of the fuse region decreases, and the probability of occurrence of the crack may increase due to a filler layer 18 filling the fuse box 17. This is because as the size of the fuse region decreases, stress may be more concentrated at the edges of the bottom surface of the fuse box 17 and the filler layer 18 may increase the stress.

### SUMMARY OF THE INVENTION

An embodiment of the present invention is directed to a fuse region for a semiconductor device that may reduce a probability of an occurrence of a crack at the edges of a bottom surface of a fuse box, and a method for forming the fuse region.

In accordance with an embodiment of the present invention, a semiconductor device having a fuse region includes: a conductive pattern and a fuse box formed to partially expose the conductive pattern which has an inclined edge on a bottom surface.

In accordance with another embodiment of the present invention, a method for forming a semiconductor device having a fuse region includes: forming a conductive pattern over a substrate; forming a protective layer formed to cover the conductive pattern; and forming a fuse box formed to partially expose the conductive pattern.

### BRIEF DESCRIPTION OF THE DRAWINGS

FIGS. 1A and 1B illustrate a fuse region of a conventional semiconductor device employing a dual fuse according to prior art.

FIG. 2 is a photograph showing a propagation of crack to a lower structure of a fuse box.

FIGS. 3A to 3C illustrate a fuse region of a semiconductor device in accordance with one embodiment of the present invention.

FIGS. 4A to 4F are cross-sectional views illustrating a method for forming a fuse region of the semiconductor device in accordance with the embodiment of the present invention.

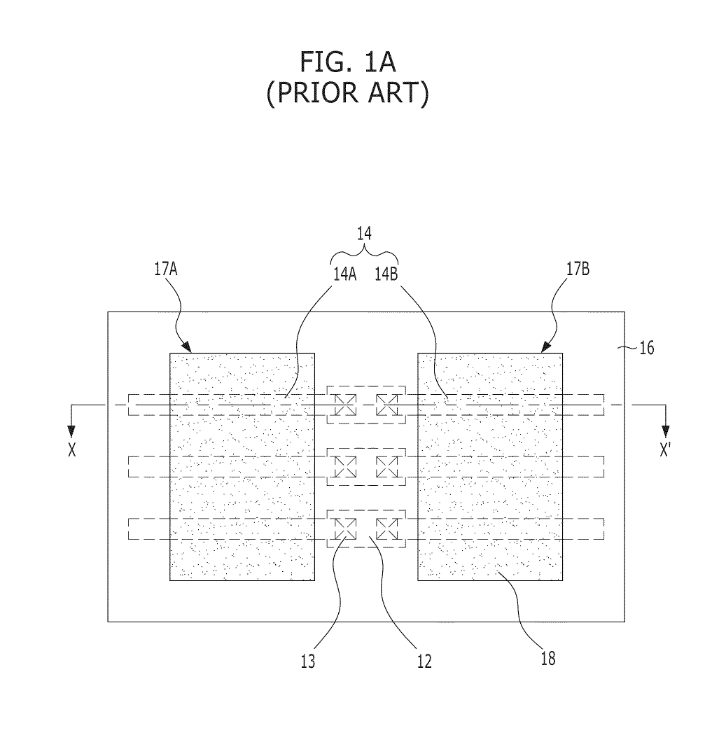

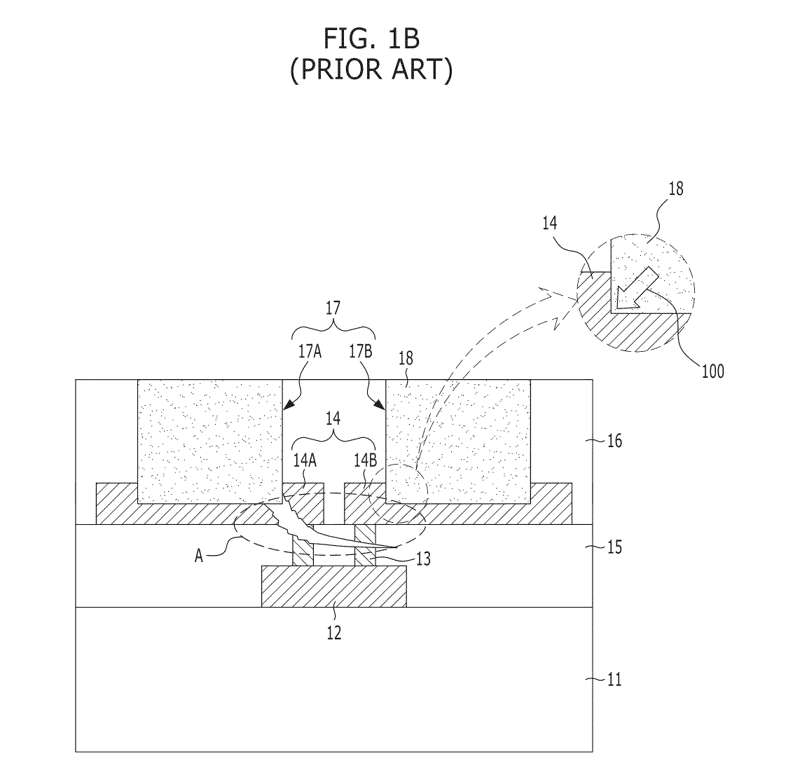

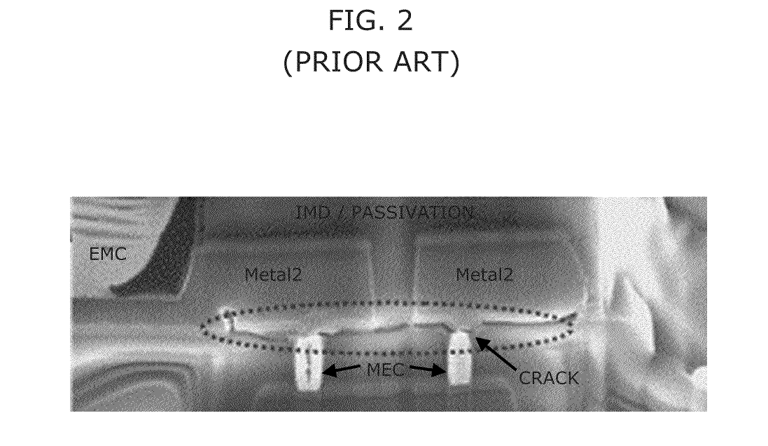

### DESCRIPTION OF SPECIFIC EMBODIMENTS

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

The embodiments of the present invention to be described hereafter provide a fuse region for a semiconductor device that may reduce a defect of a repair fuse related to a crack growth under a fuse box of a semiconductor device. For example, an edge of a bottom surface of a fuse box may be formed to be inclined to reduce a probability of a concentration of a stress at the edge of the bottom surface of the fuse box. Also, for example, the edge of a bottom surface of a fuse box may be formed to have round shape with a large radius enough to reduce a probability of a concentration of a stress on the edge of the bottom surface of the fuse box.

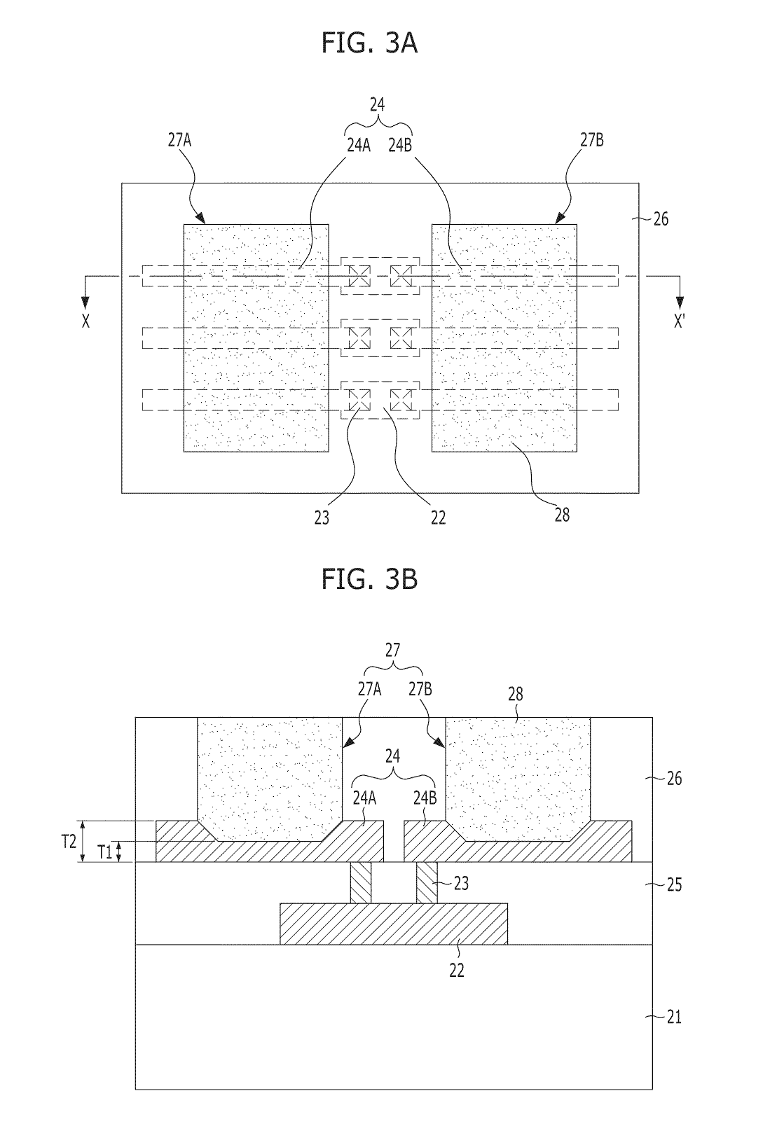

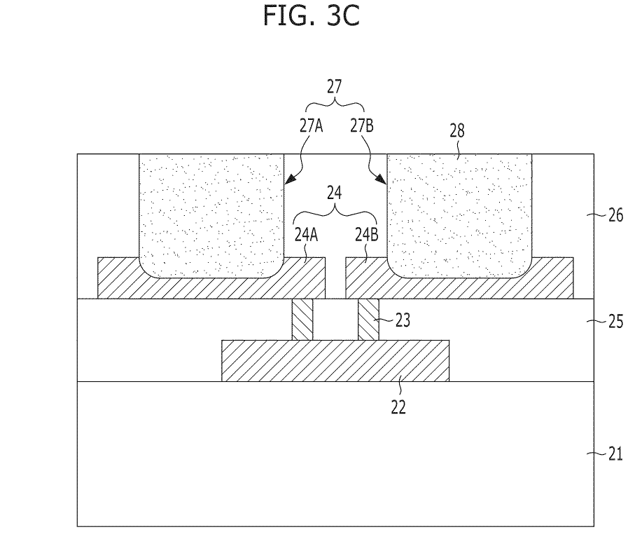

FIGS. 3A to 3C illustrate a fuse region for a semiconductor device in accordance with one embodiment of the present invention. FIG. 3A is a plan view of the fuse region, and FIG. 3B is a cross-sectional view of the fuse region obtained by cutting the fuse region of FIG. 3A along a line X-X′.

Referring to FIGS. 3A to 3C, the fuse region for a semiconductor device according to an embodiment of the present invention includes a fuse 24, a protective layer 26, a fuse box 27. The fuse 24 may be a double fuse, i.e. the fuse 24 may include a first conductive pattern 24A and a second conductive pattern 24B that are positioned on the same line over a substrate 21 with a predetermined structure formed thereon, and spaced apart from each other by a predetermined distance. Also, the fuse box 27 may include a first fuse box 27A and a second fuse box 27B. The protective layer 26 covers the structure including the double fuse 24. The first fuse box 27A and the second fuse box 27B partially expose the first conductive pattern 24A and the second conductive pattern 24B.

Here, the edges of the bottom surface may have an inclined structure of may have a round shape to reduce a probability of a concentration of the stress at the edges of the bottom surfaces of the fuse boxes 27. To be specific, the sidewalls of the upper regions of the fuse boxes 27 may have a vertical profile. The sidewalls of the lower regions of the fuse boxes 27 may have an inclined profile, and also round shape.

Also, the sidewalls provided by the first and second conductive patterns 24A and 24B may have a structure that a width of the exposed area becomes decreased as it goes from the upper regions toward the lower regions.

The thickness T1 of the double fuse 24 exposed by the fuse boxes 27 may be thinner than the thickness T2 of the double fuse 24 of a region where the fuse boxes 27 are not formed (T1<T2). This may make it relatively easy to electrically disconnect the fuse by “fuse blowing” during the repair process. Therefore, the fuse boxes 27 may have a structure where the double fuse 24, that is, the first and second conductive patterns 24A and 24B, provides the inclined sidewalls of the edges of the bottom surfaces of the fuse boxes 27. Meanwhile, the protective layer 26 may provide the inclined sidewalls of the edges of the bottom surfaces of the fuse boxes 27.

The double fuse 24 including the first and second conductive patterns 24A and 24B may be formed of a metal line. To be specific, a semiconductor device may include metal lines of a triple-layers-of-metal (TLM) structure, that is, a semiconductor device may include a first metal line, a second metal line, and a third metal line. Here, the fuse, for example, the double fuse 24 may be formed by extending, for example, a portion of the first metal line or the second metal line to the fuse region.

The protective layer 26 may be a single layer selected from the group consisting of an oxide layer, a nitride layer, an oxynitride layer, an amorphous carbon layer (ACL), and a polyimide layer, or the protective layer 26 may be a stacked layer where two or more of the layers are stacked.

Also, the fuse region of a semiconductor device according to an embodiment of the present invention may further include a wiring layer 22, an insulation layer 25, a plurality of plugs 23, and a filler layer 28. The wiring layer 22 may be formed over the substrate 21. The insulation layer 25 covers the wiring layer 22. The plurality of the plugs 23 may electrically connect the wiring layer 22 to the first and second conductive patterns 24A and 24B. The filler layer 28 may fill the fuse boxes 27.

The wiring layer 22 may be a bit line, an upper electrode of a capacitor, or a metal line. To be specific, when the double fuse 24 is formed of the first metal line, the wiring layer 22 may be a bit line or an upper electrode of a capacitor. When the double fuse 24 is formed of the second metal line, the wiring layer 22 may be the first metal line.

The insulation layer 25 may be an interlayer dielectric (ILD) layer, an inter-metal dielectric (IMD) layer, or an oxide layer having a low dielectric constant. Herein, the oxide layer having a low dielectric constant signifies an oxide layer having a smaller dielectric constant than a silicon oxide layer (SiO₂).

The plurality of the plugs 23 may electrically connect the double fuse 24 to the wiring layer 22, and the plurality of the plugs 23 may include at least one plug 23 electrically connecting the first conductive pattern 24A to the wiring layer 22 or at least one plug 23 electrically connecting the second conductive pattern 24B to the wiring layer 22.

The filler layer 28 may protect the double fuse 24 from being damaged, particularly, from being oxidized or corroded after the repair process, and the filler layer 28 may be formed of an epoxy mold compound (EMC). The EMC is a material which may be used for encapsulating a chip, and it is a mixture of approximately 30 kinds of diverse materials that are formed of an epoxy-based resin and a silica-based filler.

Since the fuse region according to an embodiment of the present invention may have the structure of which the fuse box has the inclined edges of the bottom surfaces, a probability of a concentration of the stress at the edges of the bottom surfaces of the fuse boxes 27 may decrease, and thus a probability of occurrence of a crack under the fuse boxes 27 may decrease. As a result, a probability that a non-repaired fuse is recognized as a repaired fuse, i.e. blown fuse, may decrease, and thus the repair yield and the reliability of a semiconductor device may increase.

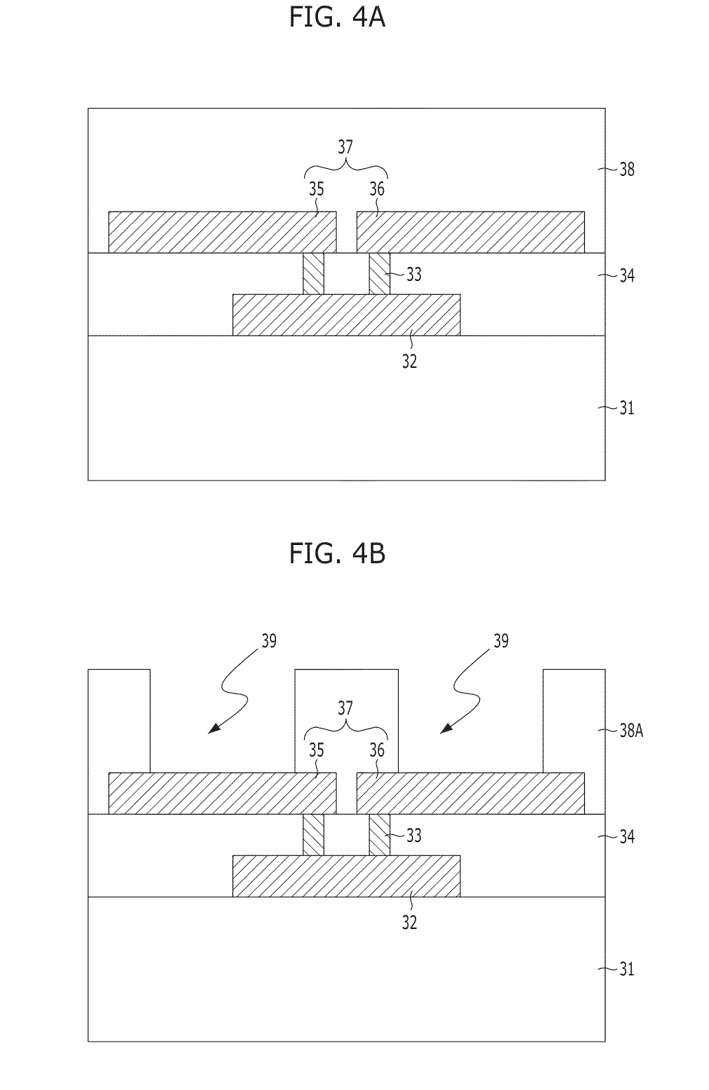

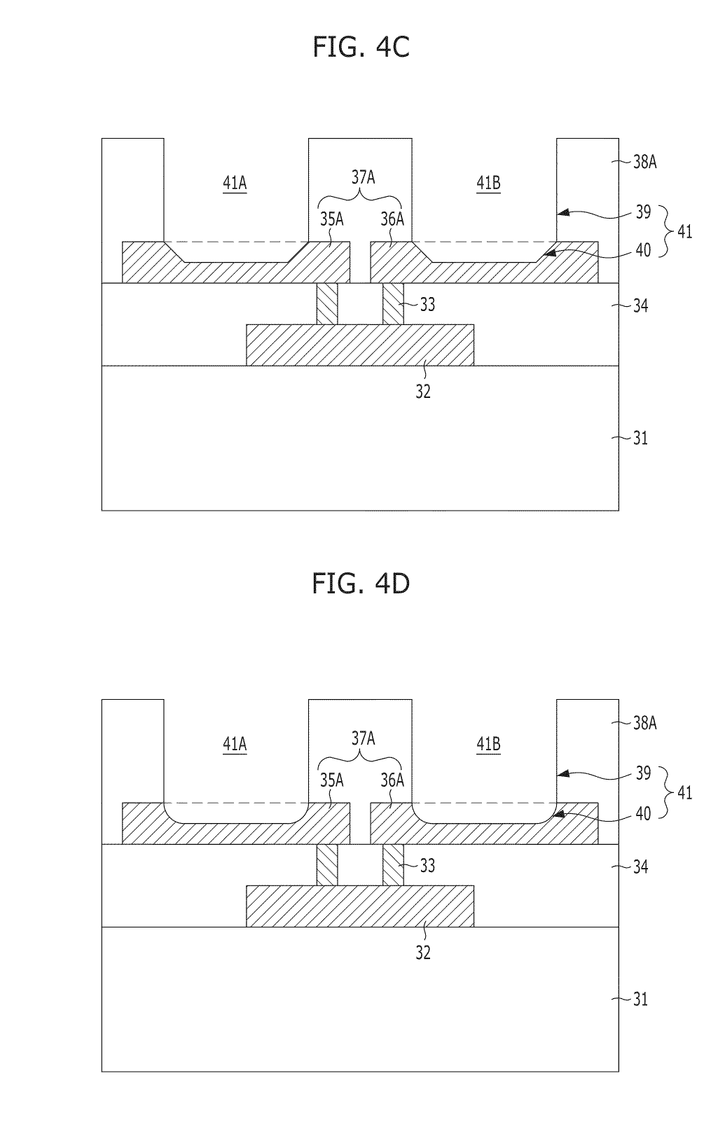

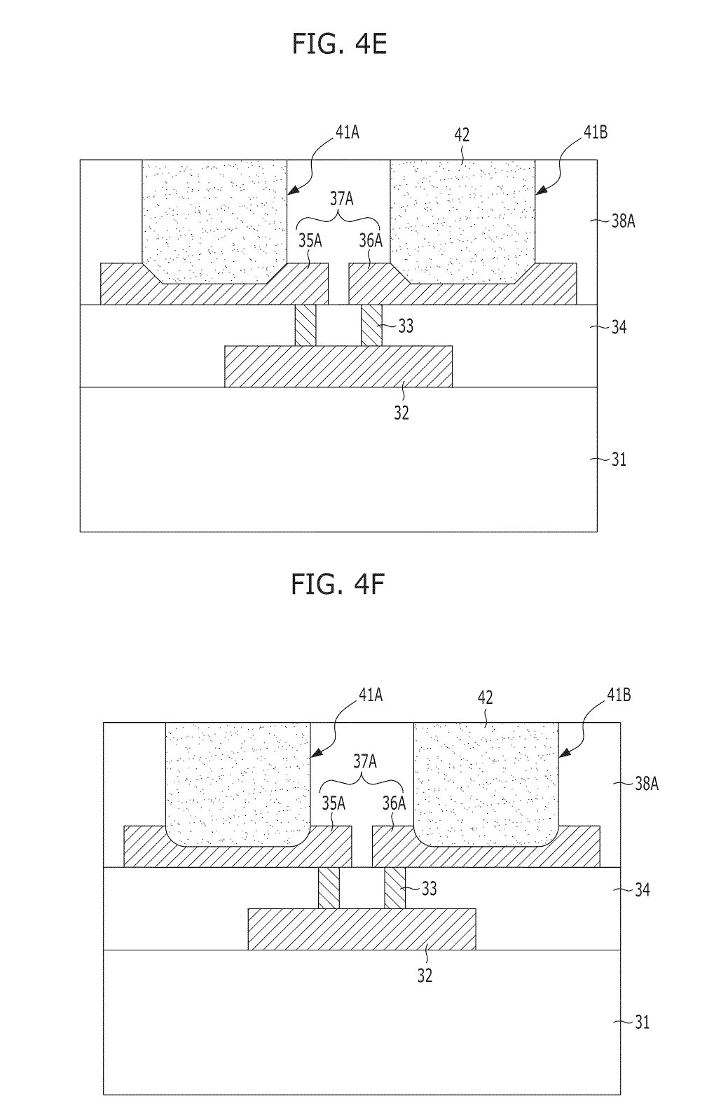

FIGS. 4A to 4F are cross-sectional views illustrating a method for forming a fuse region of the semiconductor device in accordance with an embodiment of the present invention.

Referring to FIG. 4A, a wiring layer 32 may be formed over a substrate 31 with a predetermined structure formed thereon. The wiring layer 32 may be formed by extending a portion of a bit line, an upper electrode of a capacitor, or a metal line to a fuse region. The wiring layer 32 formed in the fuse region may electrically connect a first conductive pattern and a second conductive pattern constituting a double fuse.

Subsequently, an insulation layer covering the profile of the resultant structure including the wiring layer 32 may be formed. Herein, the insulation layer may be an interlayer dielectric layer or an inter-metal dielectric layer, and the insulation layer may be formed of an oxide layer having a small dielectric constant.

Subsequently, a plurality of contact holes (not shown) may be formed to expose the upper surface of the wiring layer 32 by selectively etching the insulation layer. Then, plugs 33 are formed by filling the plurality of the contact holes with a conductive material. Hereafter, the selectively etched insulation layer will be referred to as an insulation layer pattern 34.

Subsequently, a double fuse 37 including a first conductive pattern 35 and a second conductive pattern 36 that contact the plugs 33 and spaced apart from each other on the same line by a predetermined distance may be formed over the insulation layer pattern 34. Herein, the double fuse 37 may be formed by extending a portion of a metal line to the fuse region.

Subsequently, a protective layer 38 covering the resultant structure including the double fuse 37 may be formed. The protective layer 38 may be a single layer selected from the group consisting of an oxide layer, a nitride layer, an oxynitride layer, an amorphous carbon layer, and a polyimide layer, or a stacked layer where two or more of the layers are stacked.

Referring to FIG. 4B, a mask pattern (not shown) may be formed over the protective layer 38, and a primary etch process of etching the protective layer 38 by using the mask pattern as an etch barrier to thereby may form a first pattern 39 that partially exposes the upper surfaces of the first and second conductive patterns 35 and 36 individually. Hereafter, the etched protective layer 38 will be referred to as a protective layer pattern 38A.

The first pattern 39 may be a portion of a fuse box and the sidewalls of the first pattern 39 may have a vertical profile to secure a space for making it easy to perform a targeting for blowing the fuse 37, that is, a laser targeting for electrically disconnecting the first conductive pattern 35 or the second conductive pattern 36 during a subsequent repair process. Therefore, the primary etch process may be an anisotropic dry etch process in order to make the sidewalls of the first pattern 39 have a vertical profile.

Referring to FIGS. 4C and 4D, a secondary etch process may be performed to the protective layer pattern 38A, the first conductive pattern 35, and the second conductive pattern 36 that are exposed by the first pattern 39. Through the secondary etch process, the thickness of the double fuse 37 exposed by the first pattern 39 may decrease, and a second pattern 40 with inclined or round sidewalls is formed. As a result, a fuse box 41 formed of the first pattern 39 having the sidewalls of a vertical profile and the second pattern 40 having the sidewalls of an inclined or round profile may be formed. In other words, the fuse box 41 may have an inclined or round edge of the bottom surface. Hereafter, for the sake of convenience in description, a fuse box 41 exposing the first conductive pattern 35 is referred to as a first fuse box 41A, and the fuse box 41 exposing the second conductive pattern 36 is referred to as a second fuse box 41B. Also, the first conductive pattern 35, the second conductive pattern 36, and the double fuse 37 whose thicknesses are decreased are referred to an etched first conductive pattern 35A, an etched second conductive pattern 36A, and an etched double fuse 37A.

Here, the thickness of the double fuse 37 exposed by the fuse box 41 may be decreased to facilitate the fuse disconnection during a subsequent repair process. Also, the edges of the bottom surface of the fuse box 41 may be formed to be inclined to reduce a probability of a concentration of the stress at the edges of the bottom surface of the fuse box 41. Here, the second pattern 40 may have a structure where the width is decreased as it goes from the upper region to the lower region.

The secondary etch process for forming the above-described structure may be a dry etch process. To be specific, the secondary etch process may be performed in such a manner that the etch rate in the vertical direction is faster than the etch rate in the horizontal direction based on the upper surface of the substrate 31 by controlling or by changing the pressure, bias power, source power, types of etch gas and so forth.

The primary and secondary etch processes may be performed in-situ in the same chamber in order to simplify a fabrication process.

Referring to FIGS. 4E and 4F, after a repair process is performed, the fuse boxes 41 with inclined or round edges of the bottom surface may be filled with a filler layer 42. The filler layer 42 may protect the etched double fuse 37A exposed by the fuse box 41 after the repair process from being damaged and the filler layer 42 may be formed of an epoxy mold compound (EMC).

According to the technology of the present invention, it is possible to reduce a probability of a concentration of a stress on the edge of the bottom surface of the fuse box, and thus it is possible to reduce a probability of a occurrence of a crack at the edges of a bottom surface of a fuse box by forming the edges of the bottom surface of the fuse box to be inclined or round.

Therefore, a probability that a non-repaired fuse is recognized as a repaired fuse, i.e. blown fuse, may decrease, and thus the repair yield and the reliability of a semiconductor device may increase.

While the present invention has been described with respect to the specific embodiments, it will be apparent to those skilled in the art that various changes and modifications may be made without departing from the spirit and scope of the invention as defined in the following claims.

What is claimed is:

1. A semiconductor device having a fuse region, the fuse region comprising:
a conductive pattern; and
a fuse box formed to partially expose the conductive pattern which has an inclined edge on a bottom surface.

2. The semiconductor device of claim 1, wherein the inclined edge has a round shape.

3. The semiconductor device of claim 1, wherein a thickness of the conductive pattern in a region exposed by the fuse box is thinner than a thickness of the conductive pattern in a region not exposed by the fuse box, and a upper surface of the conductive pattern in the region exposed by the fuse box has a bowl shape.

4. The fuse part of claim 1, wherein the fuse includes a metal line.

5. The semiconductor device of claim 1, further comprising:
a wiring layer formed under the fuse;
a plug arranged to electrically connect the wiring layer to the conductive pattern; and
a filler layer arranged to fill the fuse box.

6. The semiconductor device of claim 5, wherein the wiring layer is one selected from the group consisting of a bit line, an upper electrode of a capacitor, and a metal line.

7. The semiconductor device of claim 5, wherein the filler layer includes an epoxy mold compound (EMC).

8. A method for forming a semiconductor device having a fuse region, comprising:
forming a conductive pattern over a substrate;
forming a protective layer arranged to cover the conductive pattern; and
forming a fuse box arranged to partially expose the conductive pattern and have inclined edge on a bottom surface by etching the protective layer and the conductive pattern.

9. The method of claim 8, wherein the forming of the fuse box comprises:
performing a primary etching to form a sidewall of the fuse box having a vertical profile; and
performing a secondary etching to expose the conductive pattern and form an inclined edge on a bottom surface of the fuse box.

10. The method of claim 9, wherein the primary etching process and the secondary etching process are performed in-situ in the same chamber.

11. The method of claim 9, wherein the primary etching process is an anisotropic dry etch process.

12. The method of claim 9, wherein the secondary etching process is a dry etch process performed in such a manner that an etch rate in a vertical direction is faster than an etch rate in a horizontal direction.

13. The method of claim 8, wherein the fuse includes a metal line.

14. The method of claim 8, before the forming of the conductive pattern, further comprising:
forming a wiring layer over the substrate;
forming an insulation layer to cover the wiring layer; and
forming a plug formed to electrically connect the wiring layer to the conductive pattern.

15. The method of claim 14, wherein the wiring layer is one selected from the group consisting of a bit line, an upper electrode of a capacitor, and a metal line.

16. The method of claim 15, after the forming of the fuse box, further comprising:
filling the fuse box with a filler layer.

17. The method of claim 16, wherein the filler layer includes an epoxy mold compound (EMC).
